(19) United States
(12) Patent Application Publication
(10) Pub. No.: US 2012/0313638 A1
(43) Pub. Date: Dec. 13, 2012

(54) MAGNETIC FIELD SENSOR

(76) Inventors: Christian Patak, Reutlingen (DE); Stefan Weiss, Tuebingen (DE); Frederic Njikam Njimonzie, Reutlingen (DE); Frank Schaltz, Kornwestheim (DE); Paul Farber, Stuttgart (DE); Christian Bierhoff, Reutlingen (DE)

(21) Appl. No.: 13/514,550

(22) PCT Filed: Oct. 22, 2010
(86) PCT No.: PCT/EP10/65922

§ 371 Date: Aug. 30, 2012

(30) Foreign Application Priority Data
Dec. 8, 2009 (DE) 10 2009 047 624.5

(51) Int. Cl. G01R 33/04

(52) U.S. Cl. 324/253

(57) ABSTRACT

A magnetic field sensor includes a magnetizable core having a curved surface at least sectionally, a magnetization device for magnetizing the core, and a determination device for determining a magnetic field in the core.

### FIELD OF THE INVENTION

The present invention relates to a magnetic field sensor.

### BACKGROUND INFORMATION

Flux gate sensors for measuring magnetic fields are believed to be generally understood. In one variant of such flux gate sensors, a magnetically soft core is exposed to a magnetic alternating field, which drives the core into magnetic saturation using alternating field directions. A remagnetization of the core takes place whenever the magnetic alternating field is compensating an external magnetic field. The external magnetic field is able to be determined on the basis of an instant of the remagnetization in relation to the generated magnetic alternating field. Such sensors, often also referred to as MEMS sensors, can be produced as thin-film technology on a semiconductor substrate.

Unpublished German patent application DE 10 2009 028 815.5 refers to a magnetic field sensor implemented in MEMS technology, in which a coil generates a magnetic field in a block-shaped core.

### SUMMARY OF THE INVENTION

The exemplary embodiments and/or exemplary methods of the present invention are based on the objective of providing a magnetic field sensor, with whose aid the instant of the remagnetization is able to be determined more precisely.

The exemplary embodiments and/or exemplary methods of the present invention are intended to solve the stated objective by a magnetic field sensor having the features described herein. The further embodiments indicate advantageous configuration variations.

A magnetic field sensor includes a magnetizable core, a magnetization device for magnetizing the core, and a determination device for determining a magnetic field in the core, the core having a curved surface, at least in sections. In particular in a miniaturized magnetic field sensor (MEMS), the curvature of the surface of the core is able to prevent the occurrence of areas that are poorly magnetizable, so that magnetic domains of the core require no greatly differing fields for the remagnetization. A statistical fluctuation of the remagnetization instant is therefore able to be reduced and the measuring accuracy of the magnetic field sensor is improved as a result.

The core may include a longitudinal section having a positive curvature. The curvature may be positive along the entire longitudinal section. In particular, it is possible for the curvature not to exceed a predefined value along the longitudinal section. This results in a core having rounded contours, so that poorly magnetizable domains are able to be reduced further.

The core may be symmetrical in relation to its longitudinal axis. In contrast to a flat development, this makes it possible to avoid additional corners and edges of the core, so that the magnetization ability of the domains of the core becomes more uniform. This may lead to further improvements in the magnetic field determinations.

The core may have a pointed or conical end section. Because of an attendant reduction or avoidance of end domains, the remagnetization is able to be shifted to a still narrower time range, so that the measuring accuracy of the magnetic field sensor is able to be improved further.

Moreover, the core may have an asymmetrical form, e.g., in that a geometric centroid of the core is shifted along the longitudinal axis of the core through distortion of the outer dimensions of the core in the direction of an end section. For instance, this may be achieved by an essentially trapezoidal development of the core. A beginning of a remagnetization process of the core is thus able to be defined more optimally, so that a temporal reproducibility of the core's remagnetization may be improved further.

In additional specific developments, the core may have a plurality of sections which have differently sized longitudinal section surfaces along the core's longitudinal axis, so that areas having a defined magnetization are specified for starting the remagnetization process.

The exemplary embodiments and/or exemplary methods of the present invention will now be described more accurately with reference to the accompanying figures.

DETAILED DESCRIPTION OF THE DRAWINGS

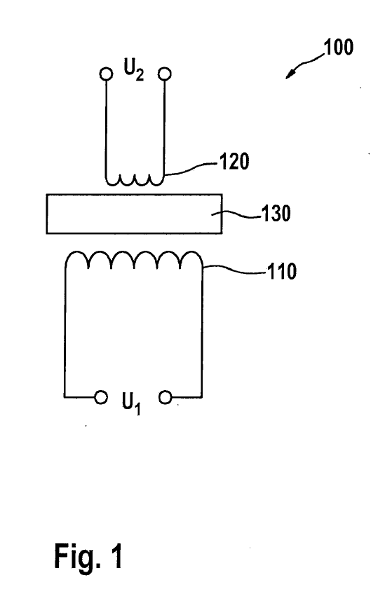

FIG. 1 shows a basic diagram of a flux gate magnetic field sensor.

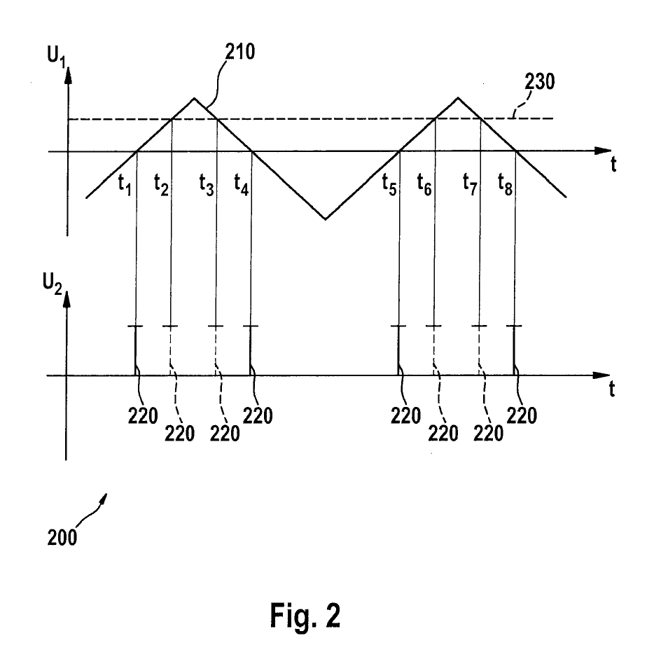

FIG. 2 shows time sequences at the magnetic field sensor from FIG. 1.

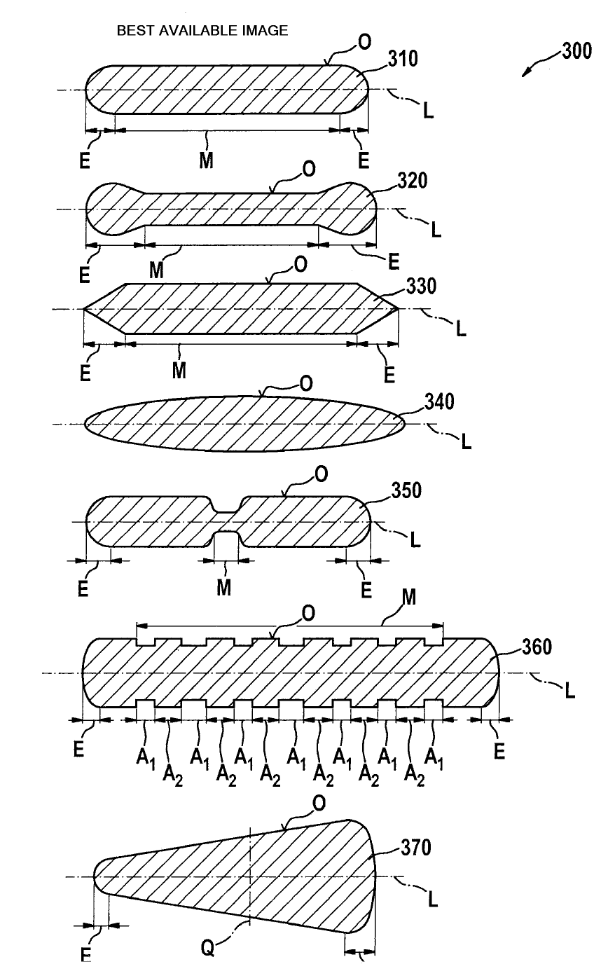

FIG. 3 shows views of different cores for the magnetic field sensor from FIG. 1.

### DETAILED DESCRIPTION

FIG. 1 shows a basic diagram of a magnetic field sensor 100. Magnetic field sensor 100 includes a first coil 110, a second coil 120, and a core 130. Magnetic field sensor 100 is designed as thin-film system. In one exemplary embodiment of a miniaturized (MEMS) magnetic field sensor 100, core 130 has a length of a few 100 μm to a few mm and a width of typically 20 to 200 μm. First coil 110 and second coil 120 may each include one or more windings, and each winding may be formed on a substrate of magnetic field sensor 100. The windings may enclose core 130 or run adjacent to core 130. An indication of the magnetic field inside core 130, such as a magnetic flux density or a magnetic flux, may be determined with the aid of second coil 120.

A periodic (e.g., triangular) voltage characteristic is applied at first coil 110, so that a magnetic field which periodically decreases and increases is generated in the region of core 130. Core 130 may be made of a magnetically soft material that has a low hysteresis.

Because of the magnetic alternating field caused by first coil 110, core 130 is subjected to periodic remagnetization when a direction of the magnetization of core 130 changes. At the remagnetization instants, a voltage U2 is induced in second coil 120 (“pickup coil”). As will be explained in the following text, an external magnetic field is able to be determined based on an instant of such a voltage pulse 220. In order to measure the instant of the pulse as precisely as possible, the pulse must be as narrow as possible in relation to a period of delta voltage U1. For this purpose, a material of core 130 is usually selected in such a way that the hysteresis of core 130 is as low as possible.

In miniaturized flux gate magnetic field sensors, there is a limit to the optimization of the smallness of the hysteresis of core 130 via a corresponding selection of material and manufacturing process of core 130 within the framework of a production process of a miniaturized system. Furthermore, as the miniaturization of coils 110, 120 and core 130 continues, the strength of pulse 220 drops, so that an evaluation of signal voltage U2 becomes more difficult.

FIG. 2 shows a diagram 200 of time characteristics of voltages U1 and U2 at magnetic field sensor 100 from FIG. 1. A characteristic 210 shown in the upper portion of diagram 200 represents a characteristic of voltage U1 at first coil 110 in FIG. 1. Pulses 220 shown in the lower portion of diagram 200 correspond to voltage pulses of U2 at second coil 120 in FIG. 1.

Characteristic 210 is a symmetrical delta signal. A magnetization of core 130 is proportional to characteristic 210. At instants t1, t4, t5 and t8, voltage U1 of characteristic 210 has the value of 0. If no external magnetic field is applied, then a remagnetization of core 130 takes place at these instants in FIG. 1, which is detectable by pulses 220 of voltage U2 of coil 120 at the same instants.

If core 130 has been premagnetized by an external magnetic field, remagnetizations of core 130 take place at instants when the external magnetic field is compensated by the magnetic field produced by first coil 110. In the illustration of FIG. 2, this is the case whenever first characteristic 210 corresponds to external magnetization 230, i.e., at instants t2, t3, t6 and t7.

From a relative position of pulses 220 with respect to each other or with respect to characteristic 210, it is possible to determine the intensity or direction of the external magnetic field. In order to perform a measurement of pulses 220 or of instants t1 through t8 as precisely as possible, pulses 220 of voltage U2 must reach a predefined voltage and be as small as possible in the process.

A ferromagnetic material like core 130 frequently has a crystal structure that includes magnetized domains. These domains are referred to as Weiss domains and have an extension in the range of approximately 10⁻⁸ to 10⁻⁴ m. The boundaries between the Weiss domains are called Bloch walls. In general, the Weiss domains are magnetized until saturated and the magnetization of different Weiss domains has different directions. In an increasing magnetic field, the Bloch walls dislocate in favor of the particular Weiss domains that are aligned in the direction of the external field. In an external field that continues to increase, more and more Weiss domains ultimately change their magnetic alignment.

The dislocation motion of the Bloch walls may be hampered by lattice faults in the crystal of the ferromagnetic material, by grain boundaries or a limitation of the magnetic material itself. This effect is called pinning. The magnetization of the ferromagnetic material thus does not increase in accordance with the externally steadily increasing magnetic field, but by small differences, the Barkhausen jumps. This prevents a uniform remagnetization of the ferromagnetic material, so that in the case of core 130 in FIG. 1, pulses 220 from FIG. 2 experience an expansion in a temporal (horizontal) direction. The core of the invention focuses on forming core 130 in such a way that a remagnetization of core 130 in a miniaturized magnetic sensor 100 is possible in a homogeneous and rapid manner. For this purpose the boundaries of core 130 are developed such that pinning effects are prevented. In addition, core 130 may be formed in such a way that a remagnetization process is influenced by the form of core 130.

FIG. 3 shows longitudinal sections of different cores 130 for magnetic field sensor 100 from FIG. 1. Each of the illustrated longitudinal sections 310 through 370 may pertain to a core 130 which is essentially flat, so that longitudinal sections 310 through 370 correspond to a plan view of core 130. Such cores may be produced in thin-film technology.

In one variant of the exemplary embodiments and/or exemplary methods of the present invention, core 130 is developed in axial symmetry with respect to a longitudinal axis L of core 130, so that the three-dimensional form of core 130 is able to be defined by the rotation of longitudinal sections 310 through 370 about their longitudinal axes, and the particular core has circular cross-sections exclusively. Intermediate forms between a flat and a round development, such as flattened or elliptical cross-sections, are likewise possible. The production of such cores may require a production method other than thin-film technology.

Longitudinal sections 310 through 370 all have sections at which a surface O of core 130 is curved. In these sections, shifting of Bloch walls through a delimitation of core 130 is hampered to a lesser degree. In all longitudinal sections 310 through 370, a ratio between length and width of the particular longitudinal section is selected such that the movement of the Bloch walls is hampered as little as possible. A core 130 formed in this way is known as “narrow core” in the literature.

First longitudinal section 310 has the shape of a rectangle with rounded end sections E. The roundings of end sections E may merge in pair-wise manner, so that end sections E have the form of semicircles or elliptical sections.

Second longitudinal section 320 corresponds to first longitudinal section 310, but additionally includes a tapered section in a center section M between the ends. Transitions between end sections E and tapered section M may be rounded. Because of tapered section M, the field strength required for the abrupt magnetization of core 130 is able to be controlled via the form of core 130. There is increased magnetic flux density in the region of tapered section M, which promotes rapid remagnetization of section M. Given an identical electrical signal shape 210, thickened end sections E lead to smaller magnetic fields in FIG. 2, which offers advantages in the component with regard to measuring range and alignment. This effect also improves the temporal reproducibility of pulses 220 in FIG. 2 and thus reduces the noise of miniaturized magnetic field sensor 100 from FIG. 1.

Third longitudinal section 330 includes a rectangular center region M, which transitions into two end sections E having a triangular form in each case. The peaked shape of triangular end sections E avoids poor magnetization in these regions and furthermore offers a starting and end point for a Bloch wall that is shifting through core 130. Due to the lack of end domains, the entire material of core 130 in longitudinal section 330 is able to contribute to signal 220.

Fourth longitudinal section 340 has the form of a symmetrical ellipse. With regard to the advantages of this longitudinal section, the above comments in connection with third longitudinal section 330 apply. In addition, the elliptical form of longitudinal section 340 prevents the occurrence of regions that are poorly accessible to an external magnetic field.

Fifth longitudinal section 350 corresponds to first longitudinal cross-section 310 but has a pronounced narrow region in a center section M. This pronounced narrow region causes an extreme flux density excess in this area, which immediately leads to a remagnetization of adjoining regions.

Sixth longitudinal section 360 results from the basic form of first longitudinal section 310 and has end sections E that have an even flatter form; it also has a segmented center region M. In segmented center region M, segments Al having a first width alternate with segments A2 having a second width (in the horizontal direction). Transitions between adjacent segments A1, A2 may be rectangular, as illustrated, or also rounded as shown in center region M of fifth longitudinal section 350. The serrated edge of longitudinal section 360 reduces pinning of Bloch walls; at the same time, regions of defined magnetization are offered for starting the remagnetization process. A ratio of widths of adjacent segments A1, A2 may be selected as desired and need not have the 1:1 ratio illustrated.

Seventh longitudinal section 370 results from a trapezoidal distortion of first longitudinal section 310. The distortion images a rectangle into a trapezoid; the base line of the trapezoid may extend parallel to longitudinal axis L of core 130 or perpendicular to longitudinal axis L, as in core 370. Because of the defined asymmetry of longitudinal section 370, a more optimally defined start of the remagnetization process and thus an improved temporal reproducibility of pulses 220 from FIG. 2 are able to be achieved. A centroid of core 130 in the seventh longitudinal section lies to the right of a transverse axis Q, which halves longitudinal axis L in core 130. The defined asymmetry of seventh longitudinal section 370 is basically applicable to any one of longitudinal sections 310 through 360 and may be realized by appropriate distortions.

A temporally precisely defined and rapid remagnetization of core 130 in miniaturized system 100 from FIG. 1 is improved by the form of core 130 illustrated by longitudinal sections 310 through 370, especially by providing rounded sections. In effect, the shape of core 130 according to the present invention makes it possible to improve the measuring accuracy of magnetic field sensor 100. In addition, other measures such as the selection of a material or a manufacturing process for core 130 or for magnetic field sensor 100 may be used to optimize the remagnetization of core 130 even further.

1-10. (canceled)

11. A magnetic field sensor, comprising
a magnetizable core;
a magnetization device for magnetizing the core; and
a determination device for determining a magnetic field in the core, wherein the core has a curved surface in at least one section, and wherein the core has two ends, the core tapering in a center section between the ends.

12. The magnetic field sensor of claim 11, wherein a longitudinal section of the core has ends that include thickened end sections.

13. The magnetic field sensor of claim 11, wherein the longitudinal section of the core has a pronounced narrow region in the center section, and wherein this narrow region has approximately 37.5% of the thickness of the ends.

14. The magnetic field sensor of claim 11, wherein a longitudinal section of the core has a segmented center section, wherein segments of a first width alternate with segments of a second width in a horizontal direction in the segmentation, and wherein the segments having the first width have a tapered region, while the segments having the second width have the same thickness as the ends.

15. The magnetic field sensor of claim 11, wherein a longitudinal section of the core has the form of a trapezoid with rounded edges.

16. The magnetic field sensor of claim 11, wherein a longitudinal section of the core has a contour having a positive curvature.

17. The magnetic field sensor of claim 11, wherein the core has a longitudinal axis, in relation to which it has an axially symmetrical configuration.

18. The magnetic field sensor of claim 11, wherein a longitudinal section of the core has an end section that tapers to a peak.

19. The magnetic field sensor of claim 11, wherein the core has an asymmetrical configuration with regard to a transverse axis situated perpendicularly to the longitudinal axis.

20. The magnetic field sensor of claim 11, wherein the surface of the core is curved in a transition region between the sections.
